(19) United States
(12) Patent Application Publication
(10) Pub. No.: US 2008/0006321 A1
(43) Pub. Date: Jan. 10, 2008

(54) Connection Unit for Photovoltaic Solar Modules

(76) Inventors: Markus Munch, Coswig (DE); Eckehard Hofmuller, Dresden (DE)

Correspondence Address: Horst M Kasper;Their Attorney, 13 Forest Drive, Warren, NJ, 07059, US

(21) Appl. No.: 11/667,498

(22) PCT Filed: Nov. 8, 2005
(86) PCT No.: PCT/EP05/11893

§ 371 Date: May 9, 2007

(30) Foreign Application Priority Data
Nov. 9, 2004 (DE) 10 2004 053 942.1

(51) Int. Cl. H01L 31/048

(52) U.S. Cl. 136/251

(57) ABSTRACT

The Invention relates to a connection unit for photovoltaic solar modules with bare connection sections of the strip conductor. The aim of the Invention is to create a connection unit that can be rapidly connected to the photovoltaic solar module and enables individual parts to be easily exchanged. According to the Invention, the solar module (2) is provided with bare connection sections of the strip conductors (9). The connection unit (1) is comprised of a base body (3) and off at least one slide-in housing part (6), with interior electrical contact elements and components. The connection unit (1) is directly placed in a tight manner on the surface of a solar module (2). The base body (3) comprises a recess (4) inside of which interior electrical contact elements (5) are formed, arranged and positioned in such a manner that they can be contacted, via plug-type connections, via slide-in housing part (6) and the individual parts thereof and/or by the conductors of the connection cable (11). These contact elements (5) are connected to a switching and control unit (7) inside the slide-in housing part (6). The contacting (8) of the electrical contact elements (5) situated in a plane with the contact area on the strip conductor (9) of the solar module (2). The connection unit (1) serves to deliver power from the photovoltaic solar module (2) to consumers and to protect and prolong the serviceable live of the electrical connections and interior electronic components.

The Invention relates to a connection unit for photovoltaic solar modules and in particular for photovoltaic solar modules having plate shape with openly disposed connector sections of the strip conductor comprising the base housing part, a further casing part and interior disposed electrical connectors, which electrical connectors are connected to an electrical unit and to a connection cable.

A large number of different technical solutions are known in order to lead the electrical energy generated in the photovoltaic solar modules through suitable electrically contacted connections from the module to the consumer. It is a requirement to secure the solar cells switched together in a certain number out of individual cells, frequently also large area plate shape solar modules, against different loads with protective circuits. Here substantial temperature loads can occur both already caused by the immediate sun irradiation, as well as also through electrical load of the protective circuit in and on the connection unit. A further peculiarity are the very high requirements to the sealing capability relative to different environmental influences and to the weather stability over a long time period of years.

An arrangement comprising a panel like construction, that is a plate shape solar module, is known from the German printed patent document DE 101 54243 A1, wherein a connection unit is disposed on top of the arrangement, wherein the connection contacts protrude from the strip conductor plane of the solar module. These connection means are parts of the conductor itself, wherein the parts are bent out of the plane of the conductor path structure, wherein a contacting with an additional stamping grid is performed at the bent out parts. Also the stamping grid is to enable an improved heat dissipation and discharge out of the interior of the connection unit. This technical solution is however expensive in construction and requires an additional relatively expensive method in order to produce the contacting with a special device and to furnish with the required sealing requirements. In addition, here the plate shape solar module during the production in the region of the later connection unit under the conductor path is furnished with a separating foil or other suitable separating means, which means an additional expenditure in the production of the solar modules.

In addition this connection unit is cast such that a later exchange of for example the protective diodes is not possible.

Another technical solution is described in the European printed patent document EP 0999601 A1, wherein the connection unit comprises two parts. A removable cover unit is here disposed on a base unit. A partial casting of the interior space with a filler material is also here performed and a later exchange of individual defined interior parts, as in particular the diodes, is not possible. A further disadvantage comprises that in the conductor tracks have to be lead out as separate connectors out of the plate shape solar module in a correspondingly insulated way and have to be lead into the base unit which represents an additional production technological expense. These two parts are then led together during the assembly. The removable cover unit enables depending on the need a different switching together of the individual solar modules amongst each other.

Another form of embodiments of a connection unit is presented in the German printed patent document DE 10050614 C1, where a metallic connector box is claimed. Here the conductor tracks are also led to toward the outside by way of additional connection lines or connection strands and the conductor tracks are connected with protective diodes in the connection box. These protective diodes are then in turn connected to the metallic outer jacketing. Cooling ribs are disposed at this outer jacketing for discharging the waste heat of the protective diodes. The penetration of the complete plate shape solar module is a problem associated with this technical solution. An increased expenditure for sealing off the connection unit is required in connection with the different coefficient of expansion of the materials brought together in connection such as glass and metal. An exchange of the protective diodes without problem is also not possible.

It is an object of the present Invention to furnish a connection unit for photovoltaic solar modules, wherein the connection unit can be connected without problems quickly at the photovoltaic solar module, even though individual parts can be simply exchanged, wherein a durable and electrically good conducting contacting is made possible over the complete lifetime and wherein the connection unit is suitable with different component parts for different tasks.

This task and object is resolved according to the present Invention by the features off patent claim 1. In accordance with the present Invention here the photovoltaic solar module 2 is furnished with in part freely disposed connector sections of the two conductor tracks 9. These connection sections can also easily be produced locally at suitable positions of the assembly of the plate shape solar module. The novel connection unit 1, in particular for photovoltaic solar modules 2 in plate shape, comprises a base body 3 and at least a further casing part, the slide-in housing part 6. The novel connection unit 1 is furnished with interior disposed electrical contact and device elements and can be formed with or without connection cable. The connection unit 1 according to the present Invention is here disposed sealingly immediately at the surface of a plate shaped solar module 2. The base body 3 of the connection unit 1 possesses at least one recess 4, wherein electrical contact elements 5 are disposed lying inside of the recess 4, are constructed such, arranged such and positioned such that the contact elements 5 can be contacted with a slide-in housing part 6 and the individual parts thereof and/or the conductors of the connection cable or connection cables 11 preferably through plug connections.

These contact elements 5 form a circuit together with a switching and control unit 7 within the slide-in housing part 6. The contacting 8 of the electrical contact elements 5 is disposed in a plane with the support face on the conductor tracks 9 of the plate shape solar module 2 in a surprising novel fashion. This is associated with the advantage that on the one hand a very flat and constructive simple construction of the connection unit 1 overall becomes possible and on the other hand an automated production of the connection of the connection unit 1 can be realized. It is a further advantage that the material structure around the conductor tracks is not being changed. Here both the shape as well as the position of the electrical contact elements 5 correspond with the freely disposed connection sections 10 of the conductor tracks 9. The contact region of the electrical contact elements 5 and the freely disposed sections of the conductor tracks 9 are reliably insulated against any climactic influences permanently over relatively large areas with the aid of the base body 3 of the connection unit 1. The connection unit 1 according to the present Invention is characterized by being capable of assembly without problems and in that the slide-in housing part 6 can be de-mounted at any time easily and the connection unit 1 can be reequipped in a simple fashion for other connection conditions depending on the purpose of application of the plate shape solar module 2. Additional steps which would concern the position and shape of the conductor tracks 9 of the plate shape solar module 2 with the purpose of successive contacting are not required in contrast to the situation of the state of the art.

According to an advantageous embodiment of the interface unit 1 according to the present invention for photovoltaic solar modules, one or several connection cables 11 are connected to the electrical contact elements 5 and the switching and control unit 7 within the base housing part 3 that the base body 3 the connection cable or the connection cables 11 positions, attaches and simultaneously sufficiently insulates by way of special cable accessory parts. The essential advantage here can also be seen in a simplified construction method relative to the state of the art.

Selectively various electrical and/or electronic device elements and/or power electronic switching units and/or integrated circuits can be disposed and switchingly connected in the inwardly disposed switching and control unit 7 depending on the concrete situation of application according to special forms of the interface unit 1 for photovoltaic solar modules 2.

It is advantageous for certain cases of applications to form the complete slide in housing part 6 as a cooling body in order to optimally discharge the heat generated for example in the electronic switching and control unit 7 and in order to being able to maintain a temperature upper limit within the interface unit 1.

It is particularly advantageous to form the slide in housing part 6 of the interface unit 1 for photovoltaic solar modules 2 as plastic injection parts or cast form parts with corresponding dimensions. This assures a simple assembly and variability in the performing configuration depending on the case of application.

The passive and/or active cooling device can be disposed at or in the slide in housing part 6 for special application cases under a corresponding form of the interface unit 1 for photovoltaic solar modules 2. This cooling device can derive its energy requirements both over a foreign connection as well as also through the solar module itself The advantage comprises in particular that then also very temperature sensitive electronic device parts can be disposed and switchingly connected in the switching and control unit 7. The arrangement of a heating mechanism is also conceivable in case of particular climatic conditions.

According to a particular advantageous embodiment of the interface unit 1 for photovoltaic solar modules 2, the slide-in housing part 6 comprises a flat forming electrical connection unit 21 and/or cooling body part 22 lying thereon and/or an additional slide-in connection part of suitable construction. At least one contacting opening 23 for leading through the contact elements 5 is disposed in the floor of the plug-in form parts 20 of the interface unit 1 according to the present Invention. Furthermore an insertion region 24 is disposed, wherein the insertion region 24 corresponds to the shape and the dimensions of the flat constructing electrical connection unit 21. A receiving shaft 25 for a preformed cooling body part 22 is furnished immediately above the electrical connection unit 21, wherein the flat construction electrical connection unit 21 is connected by way of electrical contact elements 5 with the conductor tracks 9 of the plate shaped solar module 2 and with the connection cable 11. Here the plug-in form part 20 contains simultaneously the connection cable 11 and positions the connection cable 11 by way of a cable switching and attachment opening 26 and realizes at the same time the tension release fuse and the securing of the insulation.

Advantageously the flat building electrical connection unit 21 comprises a flat diode. One or several bypass or strand diodes of a different device form can be part of a circuit for further applications with the electric connection unit 21.

A battery charge controller can be integrated also at the same time in the electrical connection unit 21 with the interface unit 1 for photovoltaic solar modules 2 according to the present Invention in order to be able to perform a direct charging corresponding to specially adapted batteries.

An embodiment of the interface unit 21, wherein a D.C. to A.C. inverter circuit is integrated in the electrical connection unit 21, is possible.

The internally disposed electrical contact elements 5 of the interface unit 1 for photovoltaic solar modules 2 are advantageously furnished as spring contacts with the flat plug connectors and are positioned by a special housing inner space formation of the base body 3 and the electrical contact elements 5 are in their position such sufficiently firmly fixed that they are suitable for several plug processes without contacting problems.

Additionally one or several seals can be disposed advantageously at or around the recess 4 in the region of the resting on the plate shaped solar module 2 or at the complete outer edge at the rest face of the interface unit 21 in order to improve the sealing of the interface unit 1 relative to the photovoltaic solar module 2 and in order to protect reliably the electrical contact elements 5 or also of the device elements of the inner lying switching and control circuit 7 against interfering dirt or climatic influences. This is in particular an advantage where the plate shaped photovoltaic solar module 2 in addition to climatic loads is also subjected to further mechanical loads.

A further improvement of the insulation protection can be reached, where the recess 4 after the contacting is insulated with a suitable casting mass.

It is an advantage in particular application cases, where a self diagnostic device is integrated into the interface unit 1 for photovoltaic solar modules 2 within the switching and control circuit 7. For example thus a defective solar module can be recognized immediately in case of interference of the mode of operation or, respectively, the decrease in the generated power for example by aging can be recognized at the right time or can be displayed and the defective solar module can be exchanged thereupon.

In particular it is advantageous to construct the slide in housing part 6 such and arrange the slide in housing part 6 such that the slide in housing part 6 can be quickly exchanged without problem and depending on need for example in case of wear or use change of the photovoltaic solar module be exchanged and can be adapted to the different requirements of the use.

The essential advantage of the interface unit 1 for photovoltaic solar modules 2 according to the present Invention is associated with its simple, structured, and few device parts containing construction, its immediate coupling to the solar module, it's particular flat and fully insulating construction and a very good cooling effect. Furthermore at any time an adaptation to new connection situations can be accomplished based on a problem free exchange ability of the inner parts of the interface unit 1, such as for example in particular of the electrical contact elements and the switching and control circuit 7.

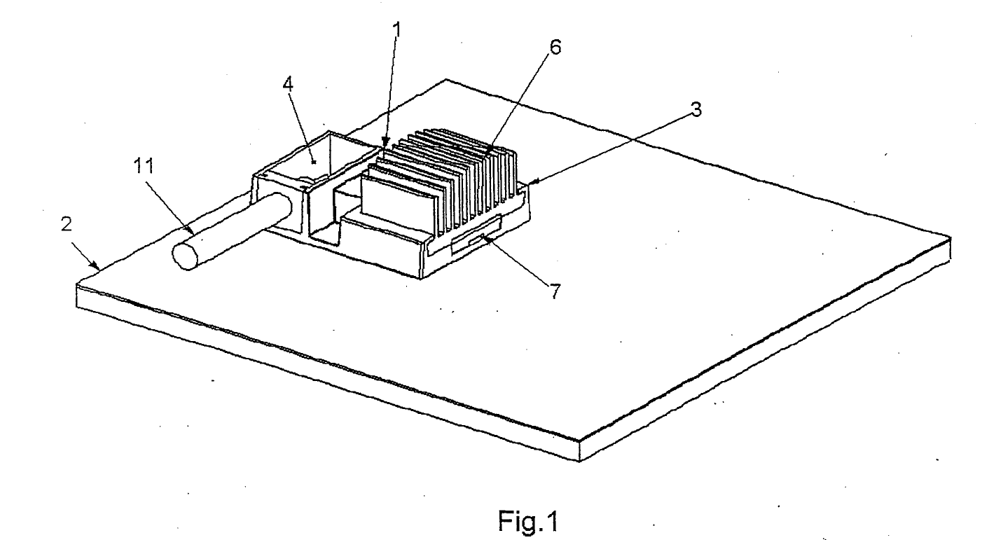

The invention is to be illustrated in more detail in the following in an embodiment example by way of the FIGS. 1 to 3.

FIG. 1 shows an interface unit 1 according to the present invention in its arrangement on a photovoltaic solar module in plate form

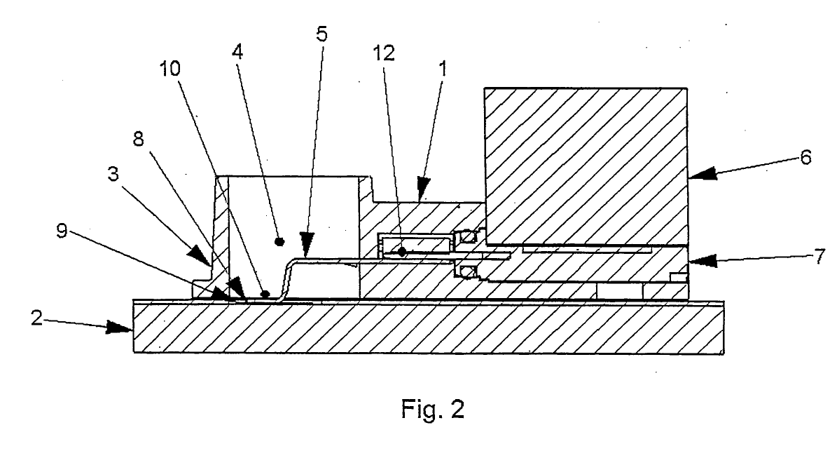

FIG. 2 shows a sectional view of an interface unit 1 according to the present invention

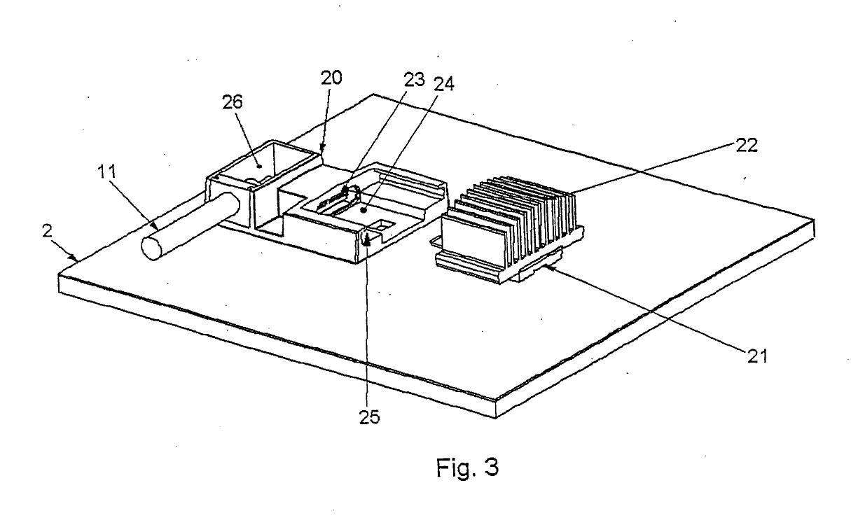

FIG. 3 shows a preferred embodiment with its individual parts

An interface unit 1 according to the present Invention for a photovoltaic plate shape solar module 2 is shown in FIGS. 1 and 2, where the interface sections 10 of the conductor tracks 9 are disposed freely and accessible from the outside, that is a kind of window is disposed in the covering layer in the surface of the plate shape solar module. The interface unit 1 comprises a base housing, the base body 3 and at least a further casing part, the slide-in housing part 6. The interface unit 21 is disposed sealingly and directly on the surface of the plate shape solar module 2. A firm seat and a secure sealing occurs, where the base body 3 is completely flat adhesively attached to the surface of the plate shape solar module 2. The base body 3 of the interface unit 1 has furthermore at least a recess 4. The electrical contact elements 5 are disposed inwardly and are such constructed and disposed in the base body 3 that the electrical contact elements 5 are switchingly connected both inside of the base body 3 as well as are disposed in a plane with the support face of the conductor tracks 9 to allow a reliable contacting 8 of the electrical contact elements 5. Here the electrical contact elements 5 are attached as double angled spring elements in the interior. The spring elements rest with one arm springingly on the surface of the conductor tracks 9 of the plate shape solar module 2 at the location of the contacting 8. If desired the arms of the electrical contact elements 5 can also be material matching connected with the conductor tracks 9. The shape and the position of the resting arms corresponds to the position, the shape and the dimensions of the conductor tracks 9 in the region of the freely disposed interface section 10. The electrical contact elements 5 end in flat plug connectors on the opposite side. The flat plug connectors are positioned such that upon sliding in of the switching and control circuit 7 necessarily a contacting with the tags or connection lugs of the electrical contact elements 5 occurs. The conductors of one or several connection cables 11 can be switchingly connected as desired also in this plug and switching connection region 12. Also a connection of the connection cable 11 or of the connection cables 11 in the region of the recess 4 is generally possible with the electrical contact elements 5. The switching and control circuit 7 is disposed and attached below the slide-in housing part 6. An additional sealing (not having reference characters in the drawing) is disposed here at the front region, which region is directed toward the tags and connection lugs for better sealing off. The slide-in housing part 6 can be constructed in different construction heights depending on the situation of the application. The slide-in housing part 6 and the switching and control circuit 7 can be furnished as a casing part or both can be formed by gluing to each other.

The base body 3 is formed as a protective envelope or shell for certain cases of application around the plug-in form part 20, wherein the base body 3 can be slid over or clicked onto the plug-in form part 20. It is shown in FIG. 3 how the connection cable 11 is connected to the base body 3, where the base body 3 is identical with the plug in form part 26 (translator's remark: should be “20”). The connection cable 11 is here attached and simultaneously positioned by a suitable, rubber elastic body, wherein the suitable rubber elastic body is arrested in the cable connection and attachment openings 26 of the plug-in form part 20 through constructive measures. In this manner there is simultaneously realized both a tension relief fuse as well as a sealing. In addition, the cable connection and attachment opening 26 is closed with a weather resistant casting mass. The attachment of the electrical contact elements 5 and their connection with the connection tags and lugs of the flat constructed electrical connection unit 21 is performed in the contacting opening 23, wherein the electrical connection unit 21 is the furnished in particular as a power diode with a large area surface. This large flat area diode is connected to the cooling body 22 in order to enable a good heat discharge. Usually the cooling body 22 comprises an aluminum strand press part.

The shape and the dimensions of the flat constructed electrical connection unit 22 (translator's remark: should be “21”) are tuned exactly to the measurements of the insertion region 24. For attachment of the two parts connected to each other, the flat constructed electrical connection unit 21 and the cooling body 22, practically corresponding to the slide-in housing part 6, a receiver shaft 25 is formed in the plug-in form part 20 in this region. The inserted parts individually or together depending on the kind of construction are arrested in the receiving shaft 25 of the plug-in form part 20 by way of suitable constructive measures on the one hand sufficiently fixed, but also again easily demountable.

The interface unit 1 according to the present invention serves for energy discharge out of the photovoltaic solar module in plate shape to possible users and in particular for the protection and the lifetime extension of the electrical contacts and connections and/or interior disposed electronic device components.

### LIST OF REFERENCE CHARACTERS

1 interface unit

2 plate shape solar module

3 base body

4 recess

5 electrical contact elements

6 plug in housing part

7 switching and control circuit

8 contacting means

9 strip conductor

10 interface section

11 connection cable

12 plug connector and switching circuit connector range

20 plug in form part

21 flat forming electrical connection unit

22 heat sink part

23 contacting opening

24 feed in region

25 receiving shaft

26 cable connection and attachment opening

1. Interface unit for photovoltaic solar modules with the freely disposed interface sections of the conductor track comprising a base housing and at least a further housing part, with interior disposed electrical contact and device elements with or without connection cable,
in particular for photovoltaic solar modules in plate shape,
characterized in that
an interface unit (1) is disposed sealingly immediately on the surface of a plate shape solar module (2),
wherein the base body (3) of the interface unit (1) has at least one recess (4),
wherein interior disposed electrical contact elements (5) are disposed in the base body (3) or in a slide-in housing part (6),
wherein the electrical contact elements (5) are switchingly connected to a switching and control circuit (7) within the slide-in housing part (6),
wherein the contacting (8) of the electrical contact elements (5) is disposed in a plane with the rest face on the conductor track (9) of the plate shape solar module (2),
wherein the shape and the position of the electrical contact elements (5) correspond to the freely disposed interface sectors (10) of the conductor tracks (9),
and wherein the base body (3) completely insulates the interface unit (1).

2. Interface unit for photovoltaic solar modules according to claim 1, characterized in that
one or several connection cables (11) are connected with the electrical contact elements (5) and the switching and control circuit (7) within the base body (3) and wherein the base body (3) positions, attaches and simultaneously insulates the connection cable or the connection cables (11) by way off special cable accessories.

3. Interface unit for photovoltaic solar modules according to claim 1, characterized in that
as selected different electrical and/or electronic device elements and/or power electronic switching units and/or integrated circuits are switchingly connected in the switching and control circuit (7).

4. Interface unit for photovoltaic solar modules according to claim, characterized in that
the slide-in housing part (6) is formed as a cooling body.

5. Interface unit for photovoltaic solar modules according to claim 1, characterized in that
the slide-in housing part (6) is formed as a plastic injection cast part or as a cast mold part.

6. Interface unit for photovoltaic solar modules according to claim 1, characterized in that
a passage and/or active cooling device is disposed at or in the slide-in housing part (6).

7. Interface unit for photovoltaic solar modules according to claim 1, characterized in that
the slide in housing part (6) comprises a flat constructed electrical connection unit (21) and the thereupon resting cooling body part (22) and/or an additional plug in connection part.

8. Interface unit for photovoltaic solar modules according to claim 7, characterized in that
at least one contacting opening (23) for feeding through the contact elements (5) is disposed in the floor of the plug-in form part (20),
in that a feed-in region (24) is furnished, wherein the feed-in region (24) in its shape and dimensions corresponds to the flat constructed electrical connection unit (21),
where a receiver shaft (25) is furnished above the feed in region (24) for a preformed cooling body (22),
wherein the flat constructed electrical connection unit (21) is connected to the conductor tracks (9) of the plate shape solar module (2) and to the connection cable (11) by way of the electrical contact elements (5),
and the plug-in form part (20) positions at the same time the connection cable (11) by way of a cable connection and attachment opening (26) and realizes the tension release fuse.

9. Interface unit for photovoltaic solar modules according to claim 8 characterized in that
the flat constructed electrical connection unit (21) comprises a flat formed diode.

10. Interface unit for photovoltaic solar modules according to claim 8, characterized in that
one or several bypass diodes or strand diodes are switchingly connected with the electrical connection unit (21).

11. Interface unit for photovoltaic solar modules according to claim 8, characterized in that
a battery charging automatic controller is integrated in the electrical connection unit (21).

12. Interface unit for photovoltaic solar modules according to claim 8, characterized in that
a DC to AC inverter is integrated in the electrical connection unit (21).

13. Interface unit for photovoltaic solar modules according to claim 1,
characterized in that
the electrical contact elements (5) are furnished as spring contacts with flat plug connectors.

14. Interface unit for photovoltaic solar modules according to claim 1
characterized in that
one or several sealings are disposed at or around the recess (4).

15. Interface unit for photovoltaic solar modules according to claim 1
characterized in that
the recess (4) after the contacting is insulated with a casting mass.

16. Interface unit for photovoltaic solar modules according to claim 1,
characterized in that
a self diagnosis device is integrated into the switching and control circuit (7).

17. Interface unit for photovoltaic solar modules according to claim 1,
characterized in that
the slide-in housing part (6) is exchangeable disposed.
